(19) United States
(12) Patent Application Publication
(10) Pub. No.: US 2026/0038782 A1
(43) Pub. Date: Feb. 5, 2026

(54) MEASUREMENT SENSOR AND SUBSTRATE PROCESSING APPARATUS INCLUDING THE SAME

(71) Applicant: SAMSUNG ELECTRONICS CO., LTD., SUWON-SI (KR)

(72) Inventors: INHYE JEONG, Suwon-si (KR); SOON KU KWON, Suwon-si (KR); WOOJIN NAM, Suwon-si (KR); SUNGGIL KANG, Suwon-si (KR); SUNG YONG PARK, Suwon-si (KR); JUNYOUNG BAE, Suwon-si (KR); CHANYEONG JEONG, Suwon-si (KR)

(21) Appl. No.: 19/187,321

(22) Filed: Apr. 23, 2025

(30) Foreign Application Priority Data
Jul. 30, 2024 (KR) 10-2024-0100806

(51) Int. Cl. H01J 37/32

(52) U.S. Cl. CPC H01J 37/32981; H01J 37/3244; H01J 37/3299; H01J 2237/24585

(57) ABSTRACT

A measurement sensor for measuring density of a material in a chamber includes a plate to be disposed within the chamber, and a plurality of sensing ports provided on the plate. Each of the plurality of sensing ports includes at least one light emitter to emit light within the chamber, and a light receiver to receive the light reflected within the chamber.

### CROSS-REFERENCE TO RELATED APPLICATION

This application claims priority under 35 U.S.C. § 119 to Korean Patent Application No. 10-2024-0100806 filed on Jul. 30, 2024, in the Korean Intellectual Property Office, the disclosure of which is incorporated by reference herein in its entirety.

### BACKGROUND

### 1. Technical Field

Embodiments of the present disclosure described herein relate to a measurement sensor and a substrate processing apparatus including the same, and more particularly, relate to a measurement sensor, capable of measuring a density of radicals inside a processing space, and a substrate processing apparatus including the same.

### 2. Discussion of Related Art

A semiconductor device may be manufactured through various manufacturing processes. Some of the manufacturing processes may be performed by utilizing plasma. Plasmas may be employed in various processes that involve etching, deposition, cleaning, or doping.

Plasmas typically involve complex reaction systems. As semiconductor devices are developed having finer line widths, research has been conducted on the ability to monitor plasma reaction systems in a processing space.

### SUMMARY

Embodiments of the present disclosure provide a measurement sensor capable of measuring a density of radicals inside a processing space and a substrate processing apparatus including the same.

Embodiments of the present disclosure provide a measurement sensor capable of measuring a density of radicals at a surface level of a substrate for performing a manufacturing process, and a substrate processing apparatus including the same.

Embodiments of the present disclosure provide a measurement sensor provided as a wireless type device to be freely movable inside or outside a processing space and a substrate processing apparatus including the same.

According to an embodiment of the present disclosure, a measurement sensor for measuring density of a material in a chamber may include a plate to be able to be disposed within the chamber, and a plurality of sensing ports provided on the plate. Each of the plurality of sensing ports may include at least one light emitter to emit light within the chamber, and a light receiver to receive the light reflected within the chamber.

According to an embodiment of the present disclosure, a substrate processing apparatus may include a chamber including a processing space defined inside the chamber, a plasma generator to generate plasma, a stage disposed in the processing space, a diffuser disposed at a ceiling part of the chamber, to supply the plasma into the processing space, and a measurement sensor to be able to be disposed on the stage to face the diffuser. The measurement sensor may include a plate to be able to be disposed on the stage, and plurality of sensing ports provided on the plate. Each of the plurality of sensing ports may include at least one light emitter to irradiate light toward the diffuser, and a light receiver to receive the light reflected from the diffuser.

According to an embodiment of the present disclosure, the substrate processing apparatus may include a chamber including a processing space defined inside the chamber, a plasma generator to supply plasma into the processing space, a stage disposed in the processing space, and a measurement sensor to be able to be disposed on the stage. The measurement sensor may include a plate, and plurality of sensing ports provided on the plate. Each of the plurality of sensing ports may include at least one light emitter to irradiate light toward an inner surface of the chamber, and a light receiver to receive the light reflected from the inner surface of the chamber.

### BRIEF DESCRIPTION OF THE FIGURES

The above and other objects and features of the present disclosure will become apparent by describing in detail embodiments thereof with reference to the accompanying drawings.

FIG. 1 is a view illustrating a substrate processing apparatus according to an embodiment of the present disclosure.

FIG. 2 and FIG. 3 are views illustrating a measurement sensor according to an embodiment of the present disclosure.

FIG. 4 is a perspective view illustrating a sensing port according to some embodiments of the present disclosure.

FIG. 5 is a perspective view of a sensing port according to an embodiment of the present disclosure.

FIG. 6 is a flowchart illustrating a method for operating a substrate processing apparatus according to an embodiment of the present disclosure.

FIG. 7 is a perspective view illustrating a sensing port according to an embodiment of the present disclosure.

FIG. 8 is a cross-sectional view taken along line I-I′ of FIG. 7.

FIG. 9 is a graph illustrating intensity data as a function of wavelengths of lights received at a sensing port according to an embodiment of the present disclosure.

FIG. 10 and FIG. 11 are perspective views illustrating sensing ports according to some embodiments of the present disclosure.

FIG. 12 is a cross-sectional view taken along line II-II′ of FIG. 11.

FIG. 13 is a cross-sectional view taken along line III-III′ of FIG. 11.

FIG. 14 is a graph illustrating intensity data as a function of wavelengths of lights received at a sensing port according to an embodiment of the present disclosure.

FIG. 15 is an exploded perspective view illustrating a measurement sensor according to an embodiment of the present disclosure.

FIG. 16 is a view illustrating a substrate processing apparatus according to an embodiment of the present disclosure.

FIG. 17 is an enlarged view of region S1 of FIG. 16.

FIG. 18 is an enlarged view of region S2 of FIG. 16.

### DETAILED DESCRIPTION

Hereinafter, embodiments of the present disclosure are described with reference to accompanying drawings such that those skilled in the art may reproduce the present disclosure. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts. The same reference numerals are used for the same components in the drawings, and redundant descriptions of the same components may be omitted. In the drawings, the thicknesses, the ratios, and the dimensions of the elements may be exaggerated for effective description of the technical contents.

According to an embodiment, a measurement sensor may be provided, which may be configured to measure density of a material over a horizontal distance and/or a height distance within the chamber. According to an embodiment, the density of a plasma radical in a chamber may be determined by measuring an absorption of light through the plasma radical between a light emitter and a light receiver.

For example, the density of a plasma radical in a chamber may be determined according to the Beer-Lambert law, which provides that the absorbance of light is proportional to concentration over a certain concentration range. The Beer-Lambert law is a combination of Lambert's law (e.g., when a ray of light—e.g., monochromatic light—passes through an absorbing medium, the intensity of the light decreases exponentially as the distance the light travels increases) and Beer's law (e.g., when light—e.g., monochromatic light—passes through an absorbing medium, the intensity of the light decreases exponentially as the concentration of the absorbing medium increases). The Beer-Lambert law may be written as:

$$A = ε l c$$

wherein, A is an absorbance of light at given wavelength, & is a molar absorptivity, l is a distance the light travels, and c a concentration of the plasma radicals. It should be understood that various expressions of these laws, or other relationships, may be used in the determination of a plasma radical density.

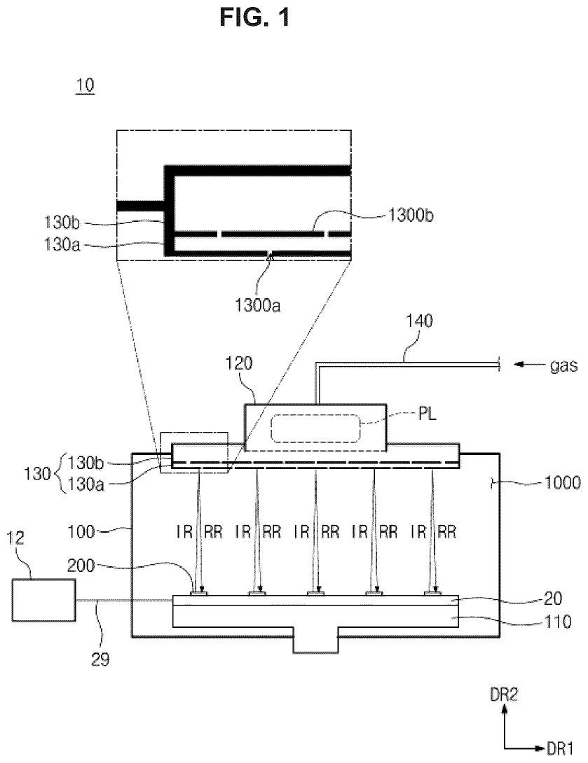

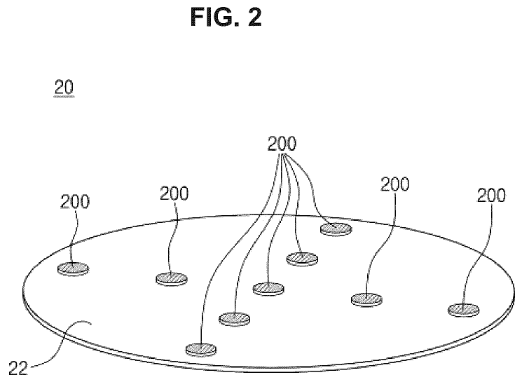

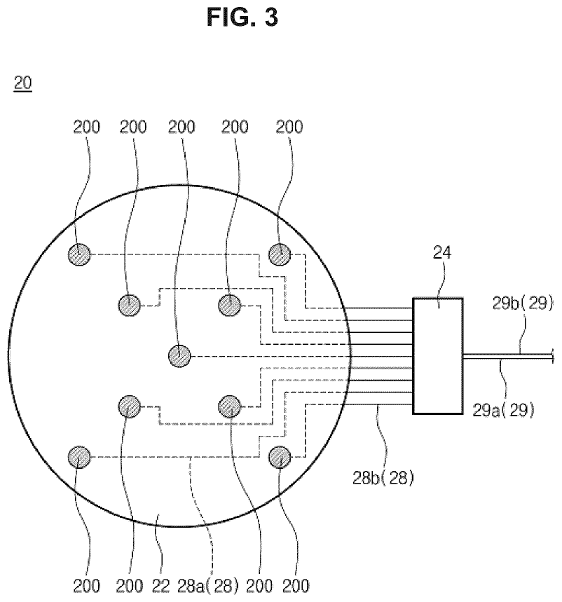

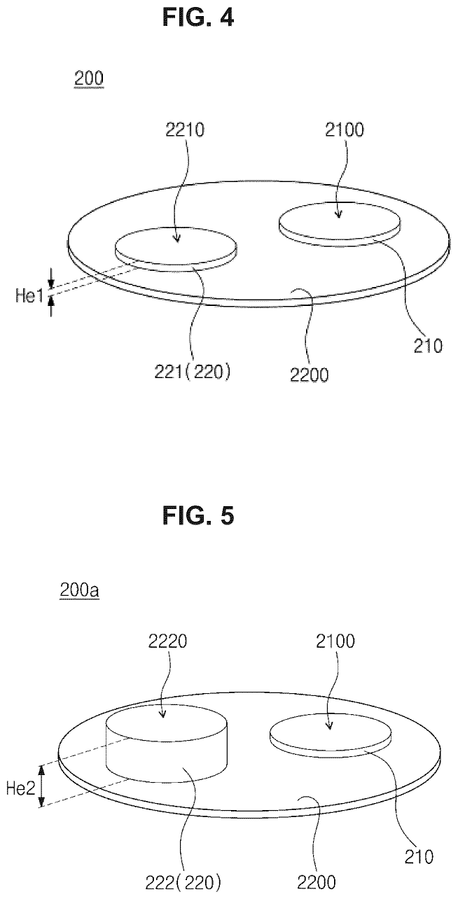

FIG. 1 is a view illustrating a substrate processing apparatus 10 according to an embodiment of the present disclosure. FIG. 2 and FIG. 3 are views illustrating a measurement sensor 20 according to an embodiment of the present disclosure. FIG. 4 is a perspective view illustrating a sensing port 200 according to an embodiment of the present disclosure.

Referring to FIGS. 1 to 4, the substrate processing apparatus 10 may include a chamber 100, a stage 110, and the measurement sensor 20. The stage 110 may be provided inside the chamber 100. The measurement sensor 20 may be disposed on the stage 110. The substrate processing apparatus 10 may perform a process for manufacturing a substrate. For example, the substrate processing apparatus 10 may include an etching device to perform an etching process, a cleaning device to perform a cleaning process, and a depositing device to perform a depositing process.

The chamber 100 may include a processing space 1000. A manufacturing process for manufacturing the substrate may be performed in the processing space 1000. The processing space 1000 may be defined inside the chamber 100. The chamber 100 may be referred to a process chamber. The chamber 100 may isolate the processing space 1000 from an external environment. The processing space 1000 may be a vacuum environment. For example, the substrate processing apparatus 10 may perform a manufacturing processes (for example, an etching process, a cleaning process, or a depositing process) in the processing space 1000 which may be the vacuum environment.

The chamber 100 may include a wall structure and a ceiling part to surround the processing space 1000. The ceiling part of the chamber 100 may be connected to the wall structure of the chamber 100.

The chamber 100 may further include a bottom part. The processing space 1000 may be defined by the wall structure, the ceiling part, and the bottom part of the chamber 100. The bottom part of the chamber 100 may be connected to the wall structure of the chamber 100.

The chamber 100 is not limited to a particular shape. For example, the wall structure may have a circular shape, an oval shape, or a rectangular shape in a plan view.

The stage 110 may be disposed inside the processing space 1000. For example, the stage 110 may be mounted on the bottom part of the chamber 100. The substrate, which is a target of the manufacturing process, may be loaded onto the stage 110. For example, to perform the manufacturing process, the substrate may be loaded onto the stage 110. In addition, at least one process of the manufacturing process, the substrate may be unloaded from the stage 110.

The stage 110 may be configured to support and/or fix the substrate in place. For example, the stage 110 may include an electrostatic chuck (ESC) to fix the substrate by electrostatic force.

The substrate processing apparatus 10 may further include a plasma generator 120 configured to generate plasma PL. The plasma PL generated from the plasma generator 120 may be supplied into the processing space 1000. For example, to perform the etching process, the plasma generator 120 may supply the plasma PL, which is generated, into the processing space 1000.

The substrate processing apparatus 10 may further include a supply pipe 140 configured to supply a process gas for plasma PL generation in the plasma generator 120. The supply pipe 140 may be connected to the plasma generator 120.

The substrate processing apparatus 10 may further a diffuser 130 configured to supply the plasma PL, which is generated in the plasma generator 120, into the processing space 1000. The diffuser 130 may diffuse or spread the plasma PL generated in the plasma generator 120, into the processing space 1000. For example, the diffuser 130 may uniformly supply the plasma PL, which is generated in the plasma generator 120, into the processing space 1000.

The diffuser 130 may be interposed between the plasma generator 120 and the processing space 1000. In addition, the diffuser 130 may be interposed between the plasma generator 120 and the stage 110. The diffuser 130 may be disposed downstream of the plasma generator 120 on the supply path of the plasma PL.

The diffuser 130 may be coupled to the chamber 100. At least a portion of the diffuser 130 may be disposed inside the processing space 1000. For example, the diffuser 130 may be coupled to the ceiling part of the chamber 100 such that the bottom surface of the diffuser 130 is exposed to the processing space 1000. The bottom surface of the diffuser 130 may form a portion of the ceiling part of the chamber 100.

The diffuser 130 may protrude downward from the ceiling part of the chamber 100. The diffuser 130 may be disposed over the stage 110. For example, the diffuser 130 may be disposed over the stage 110, and the bottom surface of the diffuser 130 may face the stage 110. Accordingly, the diffuser 130 may supply the plasma PL, which is generated in the plasma generator 120, to the stage 110 or the substrate loaded onto the stage 110 and disposed in the processing space 1000.

According to an embodiment, the diffuser 130 may include an ion blocker 130b and a shower head 130a. According to an embodiment, as illustrated in FIG. 1, the shower head 130a may be disposed under the ion blocker 130b.

The ion blocker 130b may be configured to filter out ions of the plasma PL generated from the plasma generator 120. The ion blocker 130b may include an ion filter 1300b to filter out ions. According to an embodiment, the ion filter 1300b may correspond to a lower plate of the ion blocker 130b. The ion blocker 130b may block ions from being moved into the processing space 1000. For example, the ions, which are contained in the plasma PL generated from the plasma generator 120, may be blocked by the ion blocker 130b. In addition, the ion blocker 130b may include through holes allowing radicals, which may be contained in the plasma PL, to pass through ion blocker 130b. According to an embodiment, the through holes may be extend through the ion filter 1300b of the ion blocker 130b. Accordingly, the ions contained in the plasma PL may be blocked by the ion filter 1300b, and the radicals contained in the plasma PL may pass through the ion filter 1300b through the through holes.

The shower head 130a may be configured to supply the plasma PL (for example, radicals), which may be generated from the plasma generator 120, into the processing space 1000. For example, the radicals provided from the ion blocker 130b may be supplied into the processing space 1000 through the shower head 130a. The shower head 130a may include a plurality of shower head holes 1300a allowing the plasma PL, which is generated, to pass through the shower head holes 1300a. The shower head holes 1300a may be holes extending through the lower plate of the shower head 130a. The plasma PL generated may be uniformly supplied into the processing space 1000 through the plurality of shower head holes 1300a. Accordingly, the shower head 130a may uniformly supply the plasma PL, which is generated, to the stage 110 or the substrate loaded onto the stage 110 and disposed in the processing space 1000.

The shower head 130a may be exposed to the processing space 1000. The bottom surface of the shower head 130a may form a portion of the ceiling part of the chamber 100. For example, the bottom surface of the shower head 130a may face the stage 110 or the substrate loaded onto the stage 110. According to an embodiment, an additional component may be interposed between the ion blocker 130b and the shower head 130a.

As described herein, the diffuser 130 may include the ion blocker 130b and the shower head 130a. However, embodiments of the present disclosure are not limited thereto. According to an embodiment, the shower head 130a may be omitted, or the bottom surface of the ion blocker 130b may correspond to the bottom surface of the diffuser 130.

According to an embodiment, when the shower head 130a is omitted, the ion blocker 130b may be exposed into the processing space 1000. In this case, the bottom surface of the ion blocker 130b may form the portion of the ceiling part of the chamber 100. For example, the bottom surface of the ion blocker 130b may face the stage 110 or the substrate loaded onto the stage 110 and disposed in the processing space 1000. When the shower head 130a is omitted, the ion blocker 130b may perform the function of the shower head 130a.

According to an embodiment, when the diffuser 130 includes the ion blocker 130b and the shower head 130a, the shower head 130a may be disposed over the ion blocker 130b. For example, the shower head 130a may be disposed upstream of the ion blocker 130b on the supply path of the plasma PL. In this case, the bottom surface of the ion blocker 130b may be exposed into the processing space 1000. In this case, the shower head 130a may uniformly supply the plasma PL to the ion blocker 130b, and the ion blocker 130b may block ions, which are contained in the plasma PL, and may uniformly distribute radicals onto the stage.

The measurement sensor 20 may be disposed on the stage 110 or loaded onto the stage 110. The measurement sensor 20 may be fixed onto the stage 110. The measurement sensor 20 may be separated from the stage 110 or unloaded from the stage 110. For example, the measurement sensor 20 may be detachably attached to the stage 110. For example, the measurement sensor 20 may be loaded onto the stage 110 to measure the radical density in the processing space 1000, and may be unloaded from the stage 110 after completing the measurement.

The measurement sensor 20 may be introduced into the chamber 100 or may be withdrawn from the chamber 100. For example, the measurement sensor 20 may be introduced into the chamber 100 to be loaded onto the stage 110. In addition, the measurement sensor 20 unloaded from the stage 110 may be withdrawn from the chamber 100.

The measurement sensor 20 may be disposed on the stage 110 to face the ceiling part of the chamber 100. In detail, the measurement sensor 20 may face the bottom surface of the ceiling part of the chamber 100. More specifically, the measurement sensor 20 may face the bottom surface of the diffuser 130. For example, the measurement sensor 20 may face the bottom surface of the ion blocker 130b or the bottom surface of the shower head 130a.

The measurement sensor 20 may emit light and may irradiate the light toward the ceiling part of the chamber 100. In detail, the measurement sensor 20 may include the sensing port 200 to emit the light. For example, the sensing port 200 of the measurement sensor 20 may irradiate the light toward the bottom surface of the ion blocker 130b or the bottom surface of the shower head 130a.

In detail, the measurement sensor 20 may receive a reflective light reflected inside the chamber 100. In detail, the sensing port 200 may receive a reflective light reflected from the ceiling part of the chamber 100. For example, the sensing port 200 of the measurement sensor 20 may receive a reflective light reflected from the bottom surface of the ion blocker 130b, or the reflective light reflected from the bottom surface of the shower head 130a.

The substrate processing apparatus 10 may further include a controlling system 12. The controlling system 12 may be electrically connected to the measurement sensor 20. For example, the controlling system 12 and the measurement sensor 20 may be connected to each other through a cable 29. The controlling system 12 may transmit a control signal through the cable 29 to operate the measurement sensor 20. In addition, the controlling system 12 may supply power to the measurement sensor 20 through the cable 29.

The controlling system 12 may be configured to receive data from the measurement sensor 20. For example, the controlling system 12 may receive data of the light received by the measurement sensor 20. The controlling system 12 may analyze the received data. The controlling system 12 may be configured to calculate the radical density inside the chamber 100, based on the received data.

Accordingly, the substrate processing apparatus 10 may measure the radical density inside the chamber 100.

The measurement sensor 20 may include a plate 22. The plate 22 may have a planar shape. The plate 22 may be disposed on the stage 110, and a plurality of sensing ports provided on the plate 22. The plate 22 may form an outer appearance of the measurement sensor 20. The shape of the plate 22 may correspond to the shape of the substrate provided on the stage 110. In detail, the shape of the plate 22 may be substantially the same as the shape of the substrate, when viewed in a plan view. For example, the plate 22 may be provided in the shape of a disk having the diameter of about 300 mm.

Accordingly, the measurement sensor 20 may be loaded onto the stage 110. In addition, the measurement sensor 20 may measure a radical density value approximate to a radical density value at a surface level of the substrate performed in a real manufacturing process.

A plurality of sensing ports 200 may be disposed on the plate 22. The plurality of sensing ports 200 may be disposed on a top surface of the plate 22. The plurality of sensing ports 200 may be arranged to be spaced apart from each other. According to an embodiment, the plurality of sensing ports 200 may be spaced apart from each other in a first direction DR1. According to an embodiment, the plurality of sensing ports 200 may be arranged in a diameter direction or a radius direction of the plate 22. According to an embodiment, the plurality of sensing ports 200 may be arranged radially from the center portion of the plate 22 on the top surface of the plate 22.

According to an embodiment, the plurality of sensing ports 200 may be arranged at regular positions on the top surface of the plate 22 that may be described by using angular spacing and polar coordinates. For example, in the case of four angular positions, the positions may be written as

$${θ}_{0} = 0 , {θ}_{1} = \frac{π}{2} , {θ}_{2} = π , and {θ}_{3} = \frac{3 π}{2} ,$$

which may be associated with a same polar coordinate measured from the center portion of the plate 22. In an example of FIG. 2, a first set of the sensing ports 200 arranged at a peripheral portion of the plate 22 may have a same polar coordinate, e.g., 2, and a second set of the sensing ports arranged between the first set and a center one of the sensing ports 200 may have a different polar coordinate, e.g., 1, less than the polar coordinate of the first set. While the plurality of sensing ports 200 may be arranged at regular positions, embodiments of the present disclosure are not limited thereto.

Accordingly, the measurement sensor 20 and the substrate processing apparatus 10 including the same may measure a radical density at one or more specific positions in a horizontal direction, by the plurality of sensing ports 200 arranged radially from the center portion of the plate 22.

Accordingly, the measurement sensor 20 may measure data indicative of the uniformity of the radical density formed in the horizontal direction.

The plurality of sensing ports 200 may be mounted to irradiate a light and receive a light. For example, each of the sensing ports 200 may be an optical sensor configured to irradiate light toward the diffuser 130, and receive a reflective light reflected from the diffuser 130.

The measurement sensor 20 may be a wired type device to receive power from the outside. For example, the measurement sensor 20 may include the cable 29 connected to the outside. The cable 29 may electrically connect the measurement sensor 20 to the controlling system 12. The power may be supplied to the measurement sensor 20 from an external power supply through the cable 29. In addition, the data indicative of the uniformity of the radical density formed in the horizontal direction received by the measurement sensor 20 may be transmitted to the controlling system 12 through the cable 29. In addition, an input signal (for example, the control signal) may be transmitted from the controlling system 12 to the measurement sensor 20 through the cable 29.

The measurement sensor 20 may further include a sensor controller 24 electrically connected to the plurality of sensing ports 200. The sensor controller 24 may be configured to control the operation of the plurality of sensing ports 200. Specifically, the sensor controller 24 may control the plurality of sensing ports 200 to emit a light. In addition, the sensor controller 24 may control the plurality of sensing ports 200 to receive a light.

The sensor controller 24 may select one or more of the plurality of sensing ports 200, and may control the selected sensing port(s) 200. For example, the sensor controller 24 may control one of the plurality of sensing ports 200 to emit a light.

As the sensor controller 24 may control one or more of the plurality of sensing ports 200, which may be arranged to be spaced apart from each other on the plate 22, to emit a light, the measurement sensor 20 may measure the data indicative of the radical density at the specific position of the selected sensing port(s) 200 in the horizontal direction

Th sensor controller 24 may be connected to the plurality of sensing ports 200 through wires 28. The wires 28 may be connected to the plurality of sensing ports 200, respectively. Accordingly, the sensor controller 24 may individually control the plurality of sensing ports 200 to emit a light.

Accordingly, the sensor controller 24 may select one or more of the plurality of sensing ports 200, and may control the operation of the selected sensing port(s) 200. For example, the sensor controller 24 may selectively control the operation of a center sensing port of the plurality sensing ports 200, which may be disposed at the center portion of the plate 22, and may measure the radical density at the center portion of the measurement sensor 20.

The wire 28 may include an inner wire 28a, which may be disposed in the plate 22, and an outer wire 28b which may be disposed outside the plate 22. The inner wire 28a may be embedded in the plate 22. In another example, the inner wire 28a may be disposed on a surface of the plate 22, for example, a bottom surface of the plate 22. The inner wire 28a may be connected to the outer wire 28b.

The outer wire 28b may extend outward from the plate 22. The outer wire 28b may electrically connect the inner wire 28a, which may be provided in the plate 22, to the sensor controller 24. Accordingly, the sensor controller 24 may be connected to the sensing ports 200 corresponding to the inner and outer wires 28a and 28b, through a relevant inner wire 28a and a relevant outer wire 28b. In addition, the sensor controller 24 may transmit input signals to the sensing ports 200, or may receive data corresponding to the light received at the sensing ports 200.

The sensor controller 24 may be electrically connected to the controlling system 12. The sensor controller 24 may be electrically connected to the controlling system 12 through a cable 29. The sensor controller 24 may transmit the received data to the controlling system 12 through the cable 29. In addition, the controlling system 12 may transmit the input signals to the sensor controller 24 through the cable 29. For example, the cable 29 may include an output cable 29b. The output cable 29b may transmit data from the sensor controller 24 to the controlling system 12, and an input cable 29a to transmit the input signals from the controlling system 12 to the sensor controller 24.

In addition, power may be supplied to the sensor controller 24 and the sensing ports 20 connected to the sensor controller 24 through the cable 29. The power may be supplied to the plurality of sensing ports 200 through the wires 28.

Each of the plurality of sensing ports 200 may include a light emitter 220 and a light receiver 210. The light emitter 220 may be configured to irradiate a light. The light receiver 210 may be configured to receive a light. For example, one or more of the sensing ports 200 may be a collimator configured to emit light into the chamber 100, and at least one of the sensing ports 200 may be a collimator configured to receive incident light reflected from inside. A collimator may emit light and receive incident light.

The light emitter 220 may emit light. The light emitter 220 may include a first light emitter 221 to emit a first emitted light into the processing space 1000. Specifically, the first light emitter 221 may emit the first emitted light toward the ceiling part of the chamber 100. More specifically, the first light emitter 221 may irradiate the first emitted light toward the diffuser 130. For example, the first light emitter 221 may irradiate the light toward the ion blocker 130b or the shower head 130a.

The first light emitter 221 may include a first light emitting surface 2210 to emit the light. The first light emitting surface 2210 may be a flat surface of the first light emitter 221. For example, the first light emitting surface 2210 may be disposed on the top surface of the first light emitter 221. According to an embodiment, the first light emitting surface 2210 may be parallel to the top surface of the plate 22. Accordingly, the first light emitter 221 may irradiate the first incident light upward.

The first light emitting surface 2210 may face the ceiling part of the chamber 100. Specifically, the first light emitting surface 2210 may face the diffuser 130. For example, the first light emitter surface 2210 may be directed upward to face the ion blocker 130b or the shower head 130a.

The first light emitter 221 may have a first height He1. The first light emitting surface 2210 may be disposed at the first height He1 from a lower end portion of the first light emitter 221.

The light receiver 210 may receive the reflective light. The light receiver 210 may receive a reflective light reflected from an inner surface of the chamber 10. Specifically, the light receiver 210 may receive a reflective light reflected from the ceiling part of the chamber 10. More specifically, the light receiver 210 may receive a reflective light reflected from the diffuser 130. For example, the light receiver 210 may receive the reflective light reflected from the bottom surface of the ion blocker 130b or the shower head 130a.

The light receiver 210 may include a light receiving surface 2100 to receive the reflective light. The light receiving surface 2100 may be a flat surface of the light receiver 210. For example, the light receiving surface 2100 may be provided on the top surface of the light receiver 210. According to an embodiment, the light receiving surface 2100 may be parallel to the top surface of the plate 22. Accordingly, the light receiver 210 may receive the reflective light which is provided in an upper direction.

The light receiving surface 2100 may face the ceiling part of the chamber 100. Specifically, the light receiving surface 2100 may face the diffuser 130. For example, the light receiving surface 2100 may be directed upward to face the ion blocker 130b or the shower head 130a. Accordingly, the light receiving surface 2100 may receive a reflective light reflected from the bottom surface of the ion blocker 130b, or a reflective light reflected from the bottom surface of the shower head 130a.

Each of the plurality of sensing ports 200 may further include a base 2200 disposed on the plate 22. The base 2200 may be coupled to the plate 22. The first light emitter 221 and the light receiver 210 may be provided on the base 2200. The first light emitter 221 and the light receivers 210 provided on the base 2200 may be spaced apart from each other.

FIG. 5 is a perspective view of a sensing port 200a according to an embodiment of the present disclosure.

Referring to FIG. 5, according to an embodiment, the light emitter 220 of the sensing port 200a may include a second light emitter 222 having a second height He2 different from the first height He1 of the first light emitter 221 (see FIG. 4) described herein. In detail, the second height He2 of the second light emitter 222 may be higher than the first height He1 of the first light emitter 221.

The second light emitter 222 may include a second light emitting surface 2220, which may emit light, and which is similar to the first light emitter 221. The height of the second light emitting surface 2220 may be different from the height of the first light emitting surface 2210. A position in a height direction may be referred to as a level. For example, a level of the second light emitting surface 2220 may be different from a level of the first light emitting surface 2210. Specifically, the level of the second light emitting surface 2220 from the top surface of the plate 22 may be higher than the level of the first light emitting surface 2210 from the top surface of the plate 22. For example, a height, at which the second light emitter 222 emits a light may be higher than a height at which the first light emitter 221 emits a light.

Accordingly, the path difference may be made between the traveling path of a light emitted from the second light emitter 222 and the traveling path of a light emitted from the first light emitter 221.

According to an embodiment, the second light emitter 222 may be adjustable in height. For example, the second height He2 of the second light emitter 222 may be increased or decreased. Specifically, the second light emitting surface 2220 of the second light emitter 222 may be moved in an up and down direction.

Remaining features of the second light emitter 222 may be substantially the same as features corresponding to the first light emitter 221. For example, the function of the second light emitter 222 may be substantially the same as the function of the first light emitter 221. In addition, while the first height He1 and the second height He2 may be different heights, the structure of the second light emitter 222 may be substantially the same as the structure of the first light emitter 221.

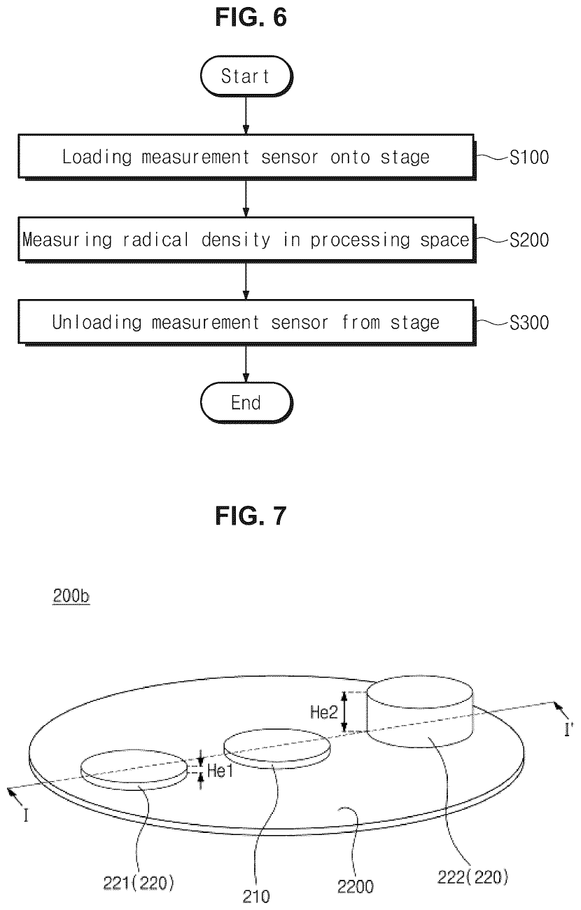

FIG. 6 is a flowchart illustrating a method for operating a substrate processing apparatus 10 according to an embodiment of the present disclosure.

Hereinafter, a method for operating the substrate processing apparatus 10 having the measurement sensor 20 will be described with reference to FIGS. 1 and 6. The method for operating the substrate processing apparatus 10 may include loading the measurement sensor 20 onto the stage 110 (S100), measuring a radical density in the processing space 1000 (S200), and unloading the measurement sensor 20 from the stage 110 (S300). Hereinafter, the method for operating the substrate processing apparatus 10 will be referred to as an “operating method” for the convenience of explanation.

The loading of the measurement sensor 20 onto the stage 110 (S100) may include disposing the measurement sensor 20 on the stage 110. The step ‘S100’ may be performed before the manufacturing process for the substrate. The measurement sensor 20 may be introduced into the chamber 100 to load the measurement sensor 20 onto the stage 110.

The measuring of the radical density of the processing space 1000 (S200) may be performed after loading the measurement sensor 20 onto the stage 110 (S100). The measurement sensor 20 may irradiate light into the processing space 1000, and may receive a reflective light reflected in the chamber 100. The measurement sensor 20 may transmit the data of the received light to the controlling system 12. The controlling system 12 may calculate the radical density of the processing space 1000, based on data received from the measurement sensor 20.

The unloading of the measurement sensor 20 from the stage 110 (S300) may be performed after measuring the radical density in the processing space 1000 (S200). In addition, the step ‘S300’ may be performed after loading the measurement sensor 20 onto the stage 110 (S100). More specifically, the step ‘S300’ may be performed after the measurement sensor 20 receives the reflective light. The measurement sensor 20 may be withdrawn out of the chamber 100 after receiving the reflective light.

The sensing port 200 or 200a described herein may include a single light emitter 221 or 222. However, embodiments of the present disclosure are not limited thereto.

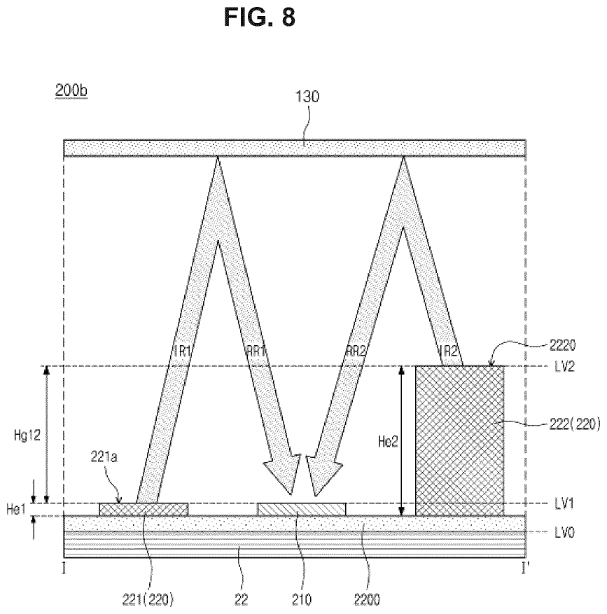

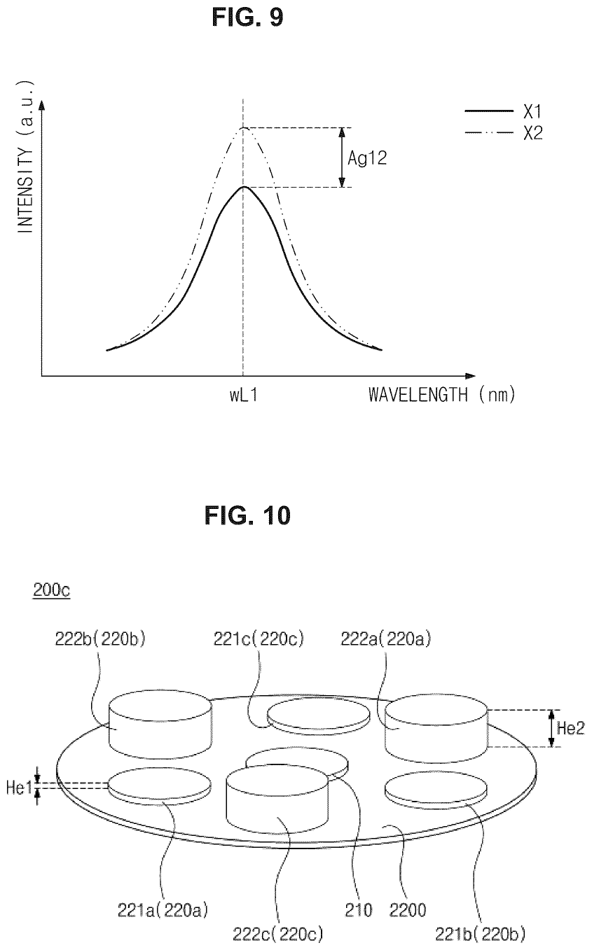

FIG. 7 is a perspective view illustrating a sensing port 200b according to an embodiment of the present disclosure. FIG. 8 is a cross-sectional view taken along line I-I′ of FIG. 7. FIG. 9 is a graph illustrating intensity data as a function of the wavelength of light received at the sensing port 200b according to an embodiment of the present disclosure.

In a method for measuring radical spatial density according to an example embodiment, light emitted from a plurality of light emitters 220 may be applied to the chamber 100 (see FIG. 8), and the light reflected by the diffuser 130 inside the chamber 100 may be received in the chamber 100 by the light receiver 210. An absorption amount of a corresponding radical wavelength band may be measured, such that the radical spatial density of an entire light path between at least one of the light emitters of the plurality of light emitters 220 and the light receiver 210 may be measured using a measured absorption amount through, for example, the Beer-Lambert Law.

Referring to FIG. 7, FIG. 8, and FIG. 9, according to an embodiment, the sensing port 200b may include a plurality of light emitters 220 having different heights and the light receiver 210. For example, the sensing port 200b may include the first light emitter 221 having the first height He1, the second light emitter 222 having the second height He2 higher than the first height He1 of the first light emitter 221, and the light receiver 210. Accordingly, a height difference Hg12 may be made between the first height He1 of the first light emitter 221 and the second height He2 of the second light emitter 222.

The light receiver 210 may be interposed between the plurality of light emitters 220. For example, the light receiver 210 may be interposed between the first light emitter 221 and the second light emitter 222. For example, the first light emitter 221 and the second light emitter 222 may be opposite to each other while interposing the light receiver 210, which may be disposed at the center portion of the base 2200, between the first light emitter 221 and the second light emitter 222.

The first light emitter 221 may emit a first incident light IR1. The first incident light IR1 may be irradiated upward. The first incident light IR1 may be incident on the ceiling part of the chamber 100 disposed over the first light emitter 221. Specifically, the first incident light IR1 may be incident into the diffuser 130. For example, the first light emitter 221 may irradiate the first incident light IR1 upward toward the diffuser 130 disposed above.

The second light emitter 222 may irradiate the second incident light IR2. The second incident light IR2 may be irradiated upward to be incident into the ceiling part (for example, the diffuser 130) of the chamber 100, which is similar to the first incident light IR1. However, the second incident light IR2 may be irradiated to a position higher than a position of the first incident light IR1.

The height of the first light emitting surface 2210 may be referred to as a first level LV1. The height of the second light emitting surface 2220 may be referred to as a second level LV2. The height of the top surface of the plate 22 may be referred to as a reference level LV0. The first level LV1 and the second level LV2 may be defined by the reference level LV0. Accordingly, the second level LV2 of the second light emitting surface 2220 may be higher than the first level LV1 of the first light emitting surface 2210.

The first incident light IR1 and the second incident light IR2 may be reflected from the ceiling part, which may be disposed above, of the chamber 100. Specifically, the first incident light IR1 and the second incident light IR2 may be reflected from the diffuser 130. A light, which may be the first incident light IR1 reflected from the ceiling part of the chamber 100 or the diffuser 130, may be referred to as a first reflective light RR1. Similarly, a light, which may be the second incident light IR2 reflected from the ceiling part of the chamber 100 or the diffuser 130, may be referred to as a second reflective light RR2.

The first reflective light RR1 and the second reflective light RR2 may travel downward. The light receiver 210 may receive the first reflective light RR1 and/or the second reflective light RR2.

The first incident light IR1 and the second incident light IR2 may be collectively referred to as an incident light. The first reflective light RR1 and the second reflective light RR2 may be collectively referred to as a reflective light. For example, the incident light may include the first incident light IR1 and the second incident light IR2, and the reflective light may include the first reflective light RR1 and the second reflective light RR2.

The first incident light IR1 and the first reflective light RR1 may be collectively referred to as a first light. For example, the first light may include the first incident light IR1 and the first reflective light RR1. The second incident light IR2 and the second reflective light RR2 may be collectively referred to as a second light. For example, the second light may include the second incident light IR2 and the second reflective light RR2.

The length difference of the optical path, which corresponds to the height difference Hg12 between the first light emitter 221 and the second light emitter 222, may be made between the length of the optical path of the first incident light IR1 and the length of the optical path of the second incident light IR2. Meanwhile, the length of the optical path of the first reflective light RR1 and the length of the optical path of the second reflective light RR2 may be substantially equal to each other. Accordingly, the length difference may be made between the length of the optical path of the first light and the length of the optical path of the second light due to the difference in the length of the optical path between the first incident light IR1 and the second incident light IR2.

According to an embodiment, when the second height He2 of the second light emitter 222 is adjusted to different heights, the height difference Hg12 between the first light emitter 221 and the second light emitter 222 may be varied. For example, when the second height He2 of the second light emitter 222 is increased, the height difference Hg12 between the first light emitter 221 and the second light emitter 222 may be increased. When the second height He2 of the second light emitter 222 is decreased, the height difference Hg12 between the first light emitter 221 and the second light emitter 222 may be decreased.

As illustrated in FIG. 9, the intensity of the first light as a function of a wavelength may be different from the intensity of the second light as a function of a wavelength. For example, the intensity of the first light may be weaker than the intensity of the second light. In FIG. 9, reference numeral ‘X1’ refers to the first light, and reference numeral ‘X2’ refers to the second light. The difference in intensity between the first light and the second light may have a maximum value Ag12 at a specific wavelength wL1. The difference in intensity between the first light and the second light may be decreased, as the wavelength becomes less than the specific wavelength wL1. The difference in intensity between the first light and the second light may be decreased, as the wavelength becomes greater than the specific wavelength wL1.

The difference in intensity between the first light and the second light may depend on the height difference Hg12 between the first light emitter 221 and the second light emitter 222, or the level difference Hg12 between the first level LV1 and the second level LV2. For example, when the height difference Hg12 between the first light emitter 221 and the second light emitter 222 is increased, the difference in intensity between the first light and the second light may be increased. When the height difference Hg12 between the first light emitter 221 and the second light emitter 222 is decreased, the difference in intensity between the first light and the second light may be decreased.

Accordingly, the radical density in a region between the first level LV1 and the second level LV2 may be calculated using the difference in intensity between the first light and the second light. For example, since the first light and the second light have the difference in optical path corresponding to the difference between the first level and the second level, the difference in intensity between the first light and the second light may depend on the radical density present in the region between the first level LV1 and the second level LV2. For example, in a case that the radical density in the region between the first level LV1 and the second level LV2 is increased, a larger amount of first light may be absorbed in the region. Accordingly, the intensity of the first light may be further decreased. In addition, the difference in intensity between the first light and the second light may be increased.

According to an embodiment, when the second height He2 of the second light emitter 222 is adjusted to different heights, the difference in intensity between the first light and the second light may be varied. For example, when the height of the second light emitter 222 is increased, the difference Ag12 in intensity between the first light and the second light may be increased. When the second light emitter 222 is decreased, the difference Ag12 in intensity between the first light and the second light may be decreased. Accordingly, in the measurement sensor 20 and the substrate processing apparatus 10 including the same, the second light emitter 222 may be set to have various heights and a radical density may be measured for each of the heights.

FIG. 10 is a perspective view illustrating a sensing port 200c according to an embodiment of the present disclosure.

Referring to FIG. 10, the sensing port 200c may include a plurality of first light emitters 221, a plurality of second light emitters 222, and the light receiver 210. For example, the plurality of first light emitters 221 and/or the plurality of second light emitters 222 may be provided in each of a plurality of sensing ports 200. For example, the first light emitter 221 and the second light emitter 222 may form a light emitting group. For example, the light emitting group may include the first light emitter 221 and the second light emitter 222. For example, a first light emitting group 220a may include a single first light emitter 221a and a single second light emitter 222a. A second light emitting group 220b may include a single first light emitter 221b and a single second light emitter 222b. A third light emitting group 220c may include a single first light emitter 221c and a single second light emitter 222c.

The plurality of first light emitters 221 and/or the plurality of second light emitters 222 may be arranged to be spaced apart from each other. The plurality of first light emitters 221 and/or the plurality of second light emitters 222 may be arranged along a peripheral portion of a top surface of the sensing port 200c. The plurality of first light emitters 221 may be arranged among the plurality of second light emitters 222. In addition, the plurality of second light emitters 222 may be arranged among the plurality of first light emitters 221.

The light receiver 210 may be disposed at the center portion of the arrangement of the plurality of first light emitters 221 and/or the center portion of the arrangement of the plurality of second light emitters 222. For example, the light receiver 210 may be disposed at the center portion of the base 2200, and the plurality of first light emitters 221 and the plurality of second light emitters 222 may be alternately arranged along an outer circumference portion of the light receiver 210.

Each of the plurality of light emitting groups 220a, 220b, and 220c may independently operate. Alternately, the plurality of light emitting groups 220a, 220b, and 220c may operate together. The light receiver 210 may receive a light reflected from the diffuser 130, as a light is irradiated by the plurality of light emitting groups 220a, 220b, and 220c.

Accordingly, the light receiver 210 may receive data of the plurality of reflective lights received. In addition, the light receiver 210 may calculate average intensity data as a function of wavelengths of the plurality of reflective lights received. Accordingly, the measurement sensor 20 may more exactly calculate the radical density.

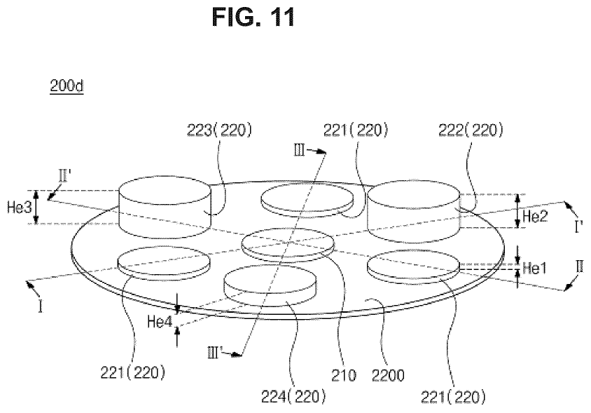

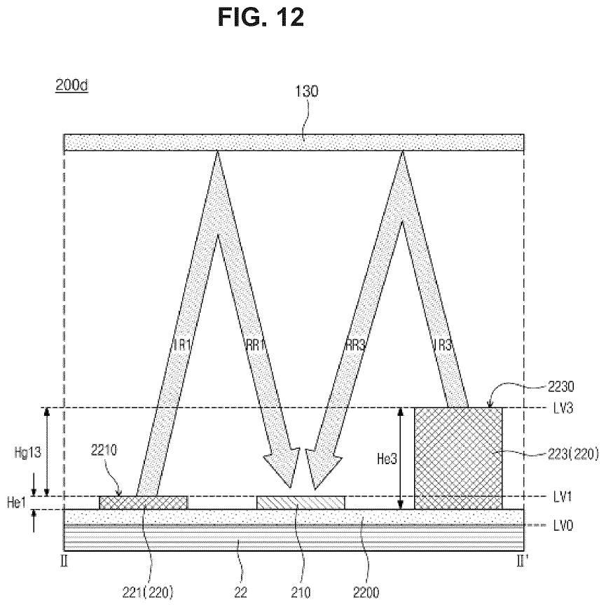

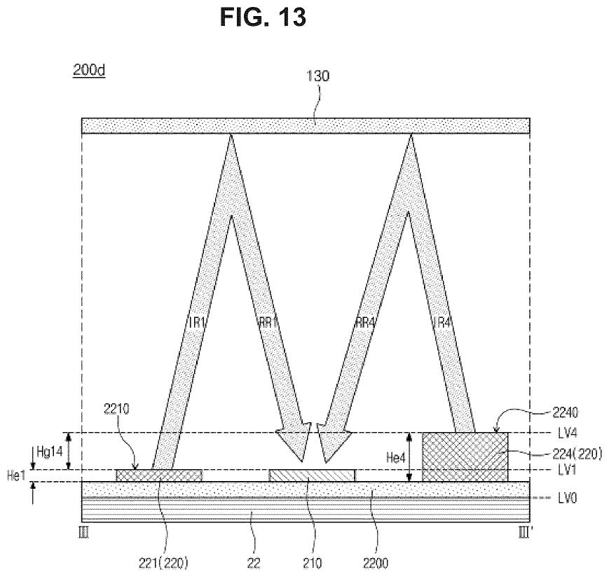

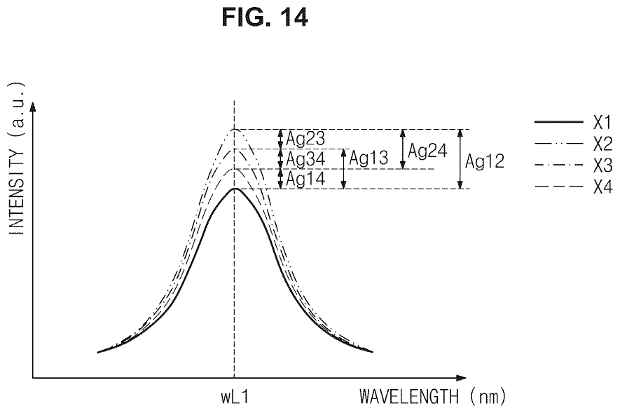

FIG. 11 is a perspective view of a sensing port 200d according to an embodiment of the present disclosure. FIG. 12 is a cross-sectional view taken along line II-II′ of FIG. 11. FIG. 13 is a cross-sectional view taken along line III-III′ of FIG. 11. FIG. 14 is a graph illustrating intensity data as a function of the wavelength of light received at a sensing port 200d according to an embodiment of the present disclosure. The cross-sectional view taken along line I-I′ of FIG. 11 may be substantially identical to FIG. 8. Accordingly, hereinafter, the sensing port 200d will be described with reference to FIG. 8 and FIGS. 11 to 14 for the convenience of explanation.

In a method for measuring radical spatial density according to an example embodiment, light emitted from a plurality of light emitters 220 may be applied to the chamber 100 (see FIG. 8), and the light reflected by the diffuser 130 inside the chamber 100 may be received in the chamber 100 by the light receiver 210. In an embodiment, an absorption amount of a corresponding radical wavelength band may be measured, wherein a radical spatial density across a horizonal direction of the base 2200 may be measured using the light receiver 210 and at least some of the plurality of first light emitters 221. In an embodiment, an absorption amount of a corresponding radical wavelength band may be measured, such that the radical spatial density in a height direction above the base 2200 may be measured using the light receiver 210 and some combination of the plurality of first light emitters 221, the second light emitter 222, a third light emitter 223, and a four light emitter 224.

Referring to FIG. 8, and FIGS. 11 to 14, the sensing port 200d may include a plurality of first light emitters 221, the second light emitter 222, a third light emitter 223, and a four light emitter 224, and the light receiver 210.

The third light emitter 223 may have a third height He3 different from the first height He1 of the first light emitter 221. Specifically, the third height He3 of the third light emitter 223 may be higher than the first height He1 of the first light emitter 221, and may be different from the second height He2 of the second light emitter 222. For example, the third height He3 of the third light emitter 223 may be higher than the first height He1 of the first light emitter 221, and may be lower than the second height He2 of the second light emitter 222.

The third light emitter 223 may include a third light emitting surface 2230 to emit the light, which is similar to the first light emitter 221 or the second light emitter 222. According to an embodiment, the third light emitting surface 2230 may be parallel to the top surface of the plate 22.

The height of the third light emitting surface 2230 may be referred to as a third level LV3. The third level LV3 may be defined by the reference level LV0.

The height of the third light emitting surface 2230 may be different from the height of the first light emitting surface 2210 and/or the height of the second light emitting surface 2220. For example, the level LV3 of the third light emitting surface 2230 may be different from the level LV1 of the first light emitting surface 2210 and/or the level LV2 of the second light emitting surface 2220. For example, the level LV3 of the third light emitting surface 2230 may be higher than the level LV1 of the first light emitting surface 2210, and may be lower than the level LV2 of the second light emitting surface 2220. For example, the height at which the third light emitter 223 emits a light may be higher than the height at which the first light emitter 221 emits a light and lower than the height at which the second light emitter 222 emits a light.

Accordingly, the path difference corresponding to the height difference Hg13 between the third light emitter 223 and the first light emitter 221 may be made between the traveling path of a light emitted from the third light emitter 223 and the traveling path of a light emitted from the first light emitter 221. The path difference corresponding to the height difference Hg23 between the third light emitter 223 and the second light emitter 222 may be made between the traveling path of a light emitted from the third light emitter 223 and the traveling path of a light emitted from the second light emitter 222.

According to an embodiment, the third light emitter 223 may be adjusted in height He3. For example, the third height He3 of the third light emitting surface 223 may be increased or decreased. Specifically, a third light emitting surface 2230 may be moved in an up and down direction.

Remaining features of the third light emitter 223 may be substantially the same as features corresponding to the first light emitter 221. For example, the function of the third light emitter 223 may be substantially the same as the function of the first light emitter 221. In addition, while the first height He1 and the third height He3 may be different heights, the structure of the third light emitter 223 may be substantially the same as the structure of the first light emitter 221.

The fourth light emitter 224 may have a fourth height He4 different from the first height He1 of the first light emitter 221. Specifically, the fourth height He4 of the fourth light emitter 224 may be higher than the first height He1 of the first light emitter 221, and different from the second height He2 of the second light emitter 222 and the third height He3 of the third light emitter 223. For example, the fourth height He4 of the fourth light emitter 224 may be higher than the first height He1 of the first light emitter 221, and may be lower than the second height He2 of the second light emitter 222 and the third height He3 of the third light emitter 223.

The fourth light emitter 224 may include a fourth light emitting surface 2240 to emit the light, which is similar to the first light emitter 221, the second light emitter 222, or the third light emitter 223. According to an embodiment, the fourth light emitting surface 2240 may be parallel to the top surface of the plate 22.

The height of the fourth light emitting surface 2240 may be referred to as a fourth level LV4. The fourth level LV4 may be defined by the reference level LV0.

The height of the fourth light emitting surface 2240 may be different from the height of the first light emitting surface 2210, the height of the second light emitting surface 2220, and/or the height of the third light emitting surface 2230. For example, the level LV4 of the fourth light emitting surface 2240 may be different from the level LV1 of the first light emitting surface 2210, the level LV2 of the second light emitting surface 2220, and/or the level LV3 of the third light emitting surface 2230. For example, the level LV4 of the fourth light emitting surface 2240 may be higher than the level LV1 of the first light emitting surface 2210, and may be lower than the level LV2 of the second light emitting surface 2220 and/or the level LV3 of the third light emitting surface 2230. For example, the height at which the fourth light emitter 224 emits a light may be higher than the height at which the first light emitter 221 emits a light, and lower than the height at which the second light emitter 222 emits a light and a height at which the third light emitter 223 emits a light.

Accordingly, the path difference corresponding to the height difference Hg14 between the fourth light emitter 224 and the first light emitter 221 may correspond to a difference between the traveling path of a light emitted from the fourth light emitter 224 and the traveling path of a light emitted from the first light emitter 221. In addition, the path difference corresponding to the height difference Hg24 between the fourth light emitter 224 and the second light emitter 222 may correspond to a difference between the traveling path of a light emitted from the fourth light emitter 224 and the traveling path of a light emitted from the second light emitter 222. In addition, the path difference corresponding to the height difference Hg34 between the fourth light emitter 224 and the third light emitter 223 may correspond to a difference between the traveling path of a light emitted from the fourth light emitter 224 and the traveling path of a light emitted from the third light emitter 223.

The fourth light emitter 224 may be variable in height. For example, the fourth height He4 of the fourth light emitter 224 may be increased or decreased. Specifically, the fourth light emitting surface 2240 may be moved in an up direction or a down direction. For example, a mechanism for adjusting the fourth height He4 of the fourth light emitter 224 may include nested cylindrical sections configured to slide within each other or extend by threaded portions integrated with the cylindrical sections. In another example, the fourth light emitter 224 may be interchangeable, and may be replaced with a different fourth light emitter 224 having a different height.

Remaining features of the fourth light emitter 224 may be substantially the same as features corresponding to the first light emitter 221. For example, the function of the fourth light emitter 224 may be substantially the same as the function of the first light emitter 221. In addition, while the first height He1 and the fourth height He4 may be different heights, the structure of the fourth light emitter 224 may be substantially the same as the structure of the first light emitter 221.

Accordingly, a plurality of height differences Hg may be made between the plurality of light emitters 220. For example, the plurality of height differences Hg may include the height difference Hg12 between the first light emitter 221 and the second light emitter 222, the height difference Hg13 between the first light emitter 221 and the third light emitter 223, the height difference Hg14 between the first light emitter 221 and the fourth light emitter 224, the height difference between the second light emitter 222 and the third light emitter 223, the height difference between the second light emitter 222 and the fourth light emitter 224, and the height difference between the third light emitter 223 and the fourth light emitter 224.

The second light emitter 222 may be disposed opposite to a first instance of the first light emitters 221 with the light receiver 210 interposed between the second light emitter 222 and the first instance of the first light emitters 221. The third light emitter 223 may be opposite to a second instance of the first light emitters 221 with the light receiver 210 interposed between the third light emitter 223 and the second instance of the first light emitters 221. The fourth light emitter 224 may be opposite to a third instance of the first light emitters 221 with the light receiver 210 interposed between the fourth light emitter 224 and the third instance of the first light emitters 221. The third instance of the first light emitters 221 may be interposed between the second light emitter 222 and the third light emitter 223. The first instance of the first light emitters 221 may be interposed between the third light emitter 223 and the fourth light emitter 224. The second instance of the first light emitters 221 may be interposed between the second light emitter 222 and the fourth light emitter 224. For example, the plurality of first light emitters 221 may be arranged along a peripheral portion of a top surface of the light receiver 210 disposed at the center portion of the base 2200, and the second, third, and fourth light emitters 222, 223, and 224 may be interposed between the plurality of first light emitters 221.

As described herein, the length of the optical path of the first light and the length of the optical path of the second light may be different due to the height difference Hg12 between the first light emitter 221 and the second light emitter 222. Accordingly, the first light and the second light, as received at the sensing port 200b, may have different intensities as a function of their wavelengths.

According to an embodiment of the present disclosure, since the second height He2 of the second light emitter 222 is higher than the first height He1 of the first light emitter 221, the intensity of the first light may be weaker than the intensity of the second light. The controlling system 12 may calculate the radical density in the region between the first level LV1 and the second level LV2 based on the intensity difference Ag12 between the first light and the second light.

Similarly, the height difference Hg13 may be made between the third light emitter 223 and the first light emitter 221. Accordingly, the length difference corresponding to the height difference Hg13 may be made between the length of the first optical path and the length of the third optical path. The third light may include a third incident light IR3 emitted by the third light emitter 223 and a reflective light (hereinafter, referred to as a “third reflective light RR3”) reflected from the ceiling part of the chamber 100 or the diffuser 130. Accordingly, the difference in intensity as a function of a wavelength may be made between the first light and the third light.

According to an embodiment of the present disclosure, since the third height He3 of the third light emitter 223 may be higher than the first height He1 of the first light emitter 221, and lower than the second height He2 of the second light emitter 222, the intensity of the third light may be stronger than the intensity of the first light and may be weaker than the intensity of the second light. The controlling system 12 may calculate the radical density in a region between the first level LV1 and the third level VL3, based on the difference Ag13 in intensity between the third light and the first light. In addition, the controlling system 12 may calculate the radical density in a region between the third level LV3 and the second level LV2, based on the difference Ag23 in intensity between the third light and the second light.

The height difference Hg14 may be made between the fourth light emitter 224 and the first light emitter 221. Accordingly, the length difference corresponding to the height difference Hg14 may be made between the length of the first optical path and the length of the fourth optical path. The fourth light may include a fourth emitted light IR4 emitted by the fourth light emitter 224 and a reflective light (hereinafter, referred to as a “fourth reflective light RR4”) reflected from the ceiling part of the chamber 100 or the diffuser 130. Accordingly, the difference in intensity as a function of a wavelength may be made between the first light and the fourth light.

According to an embodiment of the present disclosure, since the fourth height He4 of the fourth light emitter 224 may be higher than the first height He1 of the first light emitter 221 and lower than the second height He2 of the second light emitter 222 and the third height He3 of the third light emitter 223, the intensity of the fourth light may be stronger than the intensity of the first light, and weaker than the intensities of the second light and the third light. The controlling system 12 may calculate the radical density in a region between the first level LV1 and the fourth level LV4 based on the difference Ag14 in intensity between the fourth light and the first light. In addition, the controlling system 12 may calculate the radical density in a region between the fourth level LV4 and the second level LV2 based on the difference Ag24 in intensity between the second light and the fourth light. In addition, the controlling system 12 may calculate the radical density in a region between the fourth level LV4 and the third level LV3 based on the difference Ag34 in intensity between the third light and the fourth light. In FIG. 14, reference numeral ‘X1’ refers to the first light, reference numeral ‘X2’ refers to the second light, reference numeral ‘X3’ refers to the third light, and reference numeral ‘X4’ refers to the fourth light.

Accordingly, in the measurement sensor 20 and the substrate processing apparatus 10 including the same, radical densities in various height regions may be measured corresponding to the first to fourth light emitters 221, 222, 223, and 224 having different heights.

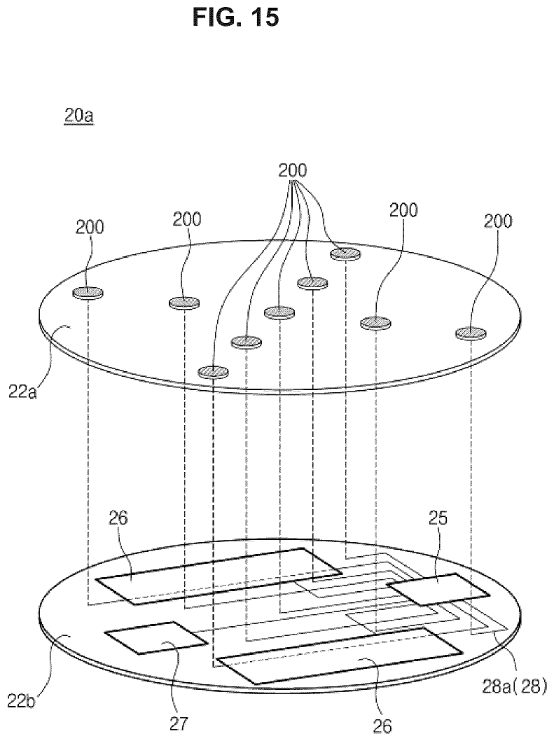

FIG. 15 is an exploded perspective view of a measurement sensor 20a according to an embodiment of the present disclosure.

Referring to FIG. 15, the measurement sensor 20a may be provided in a wireless type while operating without power supplied from the outside. For example, the external wires 28b extending to the outside may be omitted from the measurement sensor 20a. The measurement sensor 20a may include a power supplier 26 to supply power stored in the power supplier 26. For example, the power supplier 26 of the measurement sensor 20a may include a battery which is charged with electrical energy, and supplies the stored electrical energy if necessary.

Accordingly, the measurement sensor 20a may operate without power supplied from the outside. In addition, the measurement sensor 20a may be provided in a wireless type without connection to the outside through the cable 29.

The measurement sensor 20 may further include a memory device 25 to store data corresponding to the light received at the plurality of sensing ports 200. The memory device 25 may store data and may output stored data. For example, the memory device 25 may store data on a light received through the plurality of sensing ports 200. After the measurement sensor 20a is withdrawn out of the chamber 100, a worker may read data out of the memory device 25.

The memory device 25 may be electrically connected to the plurality of sensing ports 200. For example, the plurality of sensing ports 200 may be individually connected to the memory device 25 through the inner wires 28a. Accordingly, the plurality of sensing ports 200 may transmit the data on the received light to the memory device 25, and the memory device 25 may store the received data.

The measurement sensor 20a may include a wireless communication device 27 to transmit the received data to the outside. For example, the wireless communication device 27 may include a short-range wireless communication device, such as Wi-Fi, Bluetooth, or Zigbee.

The wireless communication device 27 may receive data corresponding to the light received at the plurality of sensing ports 200, and may transmit the received data to the outside. For example, the wireless communication device 27 may wirelessly transmit data, which is received from the plurality of sensing ports 200, to the controlling system 12.

The wireless communication device 27 may be electrically connected to the memory device 25. For example, the wireless communication device 27 and the memory device 25 may be connected to each other through a relevant one of the inner wires 28a. However, embodiments of the present disclosure are not limited thereto. For example, the wireless communication device 27 may be directly connected to the plurality of sensing ports 200. For example, the plurality of sensing ports 200 may be individually connected to the wireless communication device 27 through the inner wires 28a, and may directly transmit the received data to the wireless communication device 27. In this case, the memory device 25 may be omitted. In this case, the measurement sensor 20a may transmit the collected data to the controlling system 12 in real time. Accordingly, the measurement sensor 20a may be provided in a wireless type without the connection to the outside through the cable 29.

According to some embodiments, the measurement sensor 20a may include at least any one of the memory device 25 or the wireless communication device 27. For example, the measurement sensor 20a may include all the memory device 25 and the wireless communication device 27, or one of the memory device 25 or the wireless communication device 27 may be omitted from the measurement sensor 20a.

According to an embodiment, the plate 22 may include an upper plate 22a and a lower plate 22b. The upper plate 22a may face the processing space 1000. The upper plate 22a may face the ceiling part of the chamber 100 or the diffuser 130. The plurality of sensing ports 200 may be disposed on the upper plate 22a.

The lower plate 22b may be disposed on the stage 110 or loaded onto the stage 110. At least any one of the power supplier 26, the memory device 25, and the wireless communication device 27 may be embedded in the plate 22. The inner wire 28a may be embedded in the plate 22. For example, the power supplier 26, the memory device 25, and the wireless communication device 27 may be interposed between the upper plate 22a and the lower plate 22b.

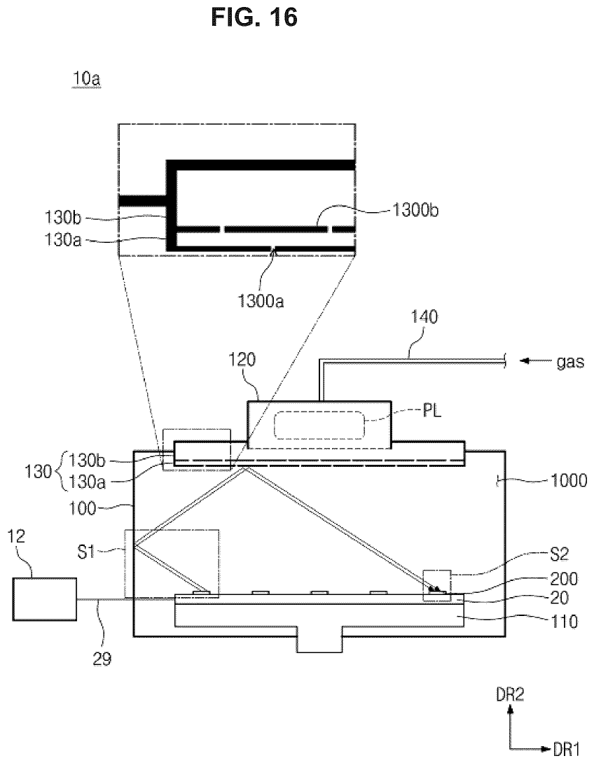

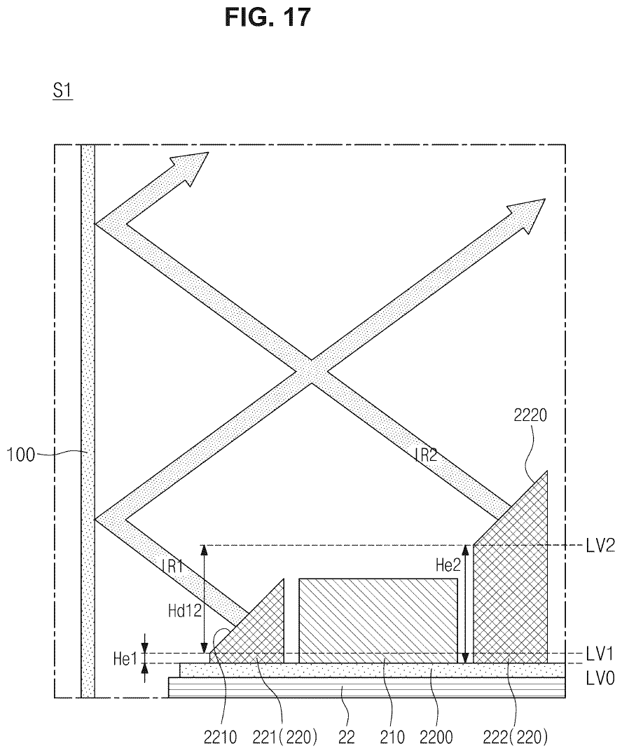

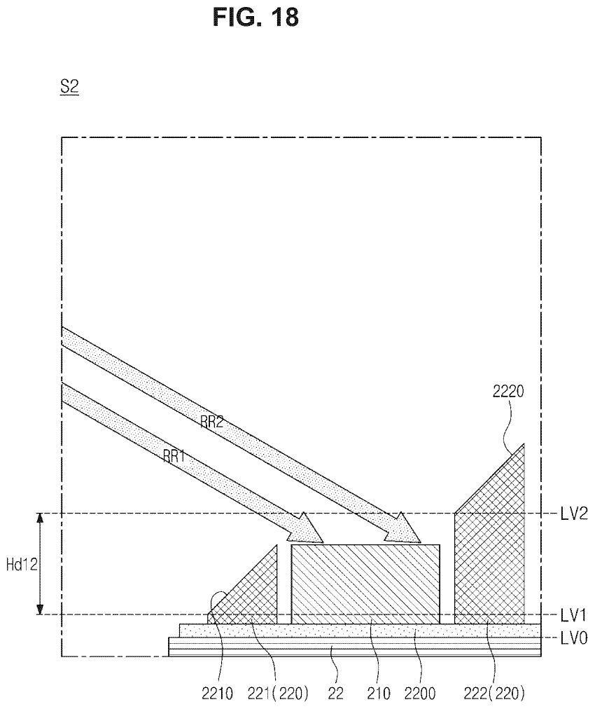

FIG. 16 is a view illustrating a substrate processing apparatus 10a according to an embodiment of the present disclosure. FIG. 17 is an enlarged view illustrating region S1 of FIG. 16. FIG. 18 is an enlarged view illustrating region S2 of FIG. 16.

Referring to FIGS. 16 to 18, the substrate processing apparatus 10a may include the measurement sensor 20 to irradiate a light toward an inner surface of the chamber 100. For example, the substrate processing apparatus 10a may include the measurement sensor 20 to irradiate a light toward a wall surface or a ceiling surface of the chamber 100. The measurement sensor 20 may have the plurality of sensing ports 200, and each of the plurality of sensing ports 200 may include a light emitter 220 configured to irradiate light toward the wall surface of the chamber 100.

The light emitter 220 may include the first light emitter 221 having a first light emitting surface 2210 which is inclined to face the wall surface of the chamber 100. The first light emitting surface 2210 may be inclined with respect to the top surface of the plate 22. The first light emitter 221 may emitted the first incident light IR1 to be inclined with respect to the wall surface of the chamber 100.

The light emitter 220 may further include a second light emitter 222 having a second light emitting surface 2220 which is inclined to face the wall surface of light emitter 220. The second light emitting surface 2220 may be inclined with respect to the top surface of the plate 22. The second light emitter 222 may irradiate the second incident light IR2 to be inclined with respect to the wall surface of the chamber 100.

The first light emitter 221 and the second light emitter 222 may irradiate the first incident light IR1 and the second incident light IR2 toward a specific wall surface of the chamber 100.

A first height of the first light emitter 221 may be different from a second height of the second light emitter 222. Accordingly, a height at which the first light emitter 221 emits a light may be different from a height at which the second light emitter 222 emits a light. The height at which the first light emitter 221 emits a light may be a height of the center portion of the first light emitting surface 2210. The height at which the second light emitter 222 emits a light may be a height of the center portion of the second light emitting surface 2220.

The height of the first light emitter 221 may be different than the height of the second light emitter 222. The first light emitter 221 may have a first height He1 from the base 2200 to the lower end portion of the first light emitting surface 2210. In addition, the second light emitter 222 may have a second height He2 from the base 2200 to a lower end portion of the second light emitting surface 2220. Accordingly, a height difference Hd12 may be made between the first light emitter 221 and the second light emitter 222.

The height a first lower end portion of the first light emitting surface 2210 may be referred to as a first level LV1. The height of a second lower end portion of the second light emitting surface 2220 may be referred to as a second level LV2. The height of the top surface of the plate 22 may be referred to as the reference level LV0. The first level LV1 and the second level LV2 may be defined by the reference level LV0.

It should be understood that a difference between a height a first upper end portion of the first light emitting surface 2210 and a height a second upper end portion of the second light emitting surface 2220 may be the same as a difference in height between the first level LV1 and the second level LV2, or a difference in height between a region of the first light emitting surface 2210 where the first incident light IR1 is emitted and a region of the second light emitting surface 2220 where the second incident light IR2 is emitted. For example, various points may be used to determine the distance that the light travels for each of the light emitting surfaces.

The level difference Hd12 between the first level LV1 and the second level LV2 may correspond to the height difference Hd12 between the first light emitter 221 and the second light emitter 222. For example, the first level LV1 may be a distance from the reference level LV0 to the first lower end portion of the first light emitting surface 2210, and the second level LV2 may be a distance from the reference level LV0 to the second lower end portion of the second light emitting surface 2220.

Each of the plurality of sensing ports 200 may include the light receiver 210 to receive a light reflected from the wall surface of the chamber 100. The light receiver 210 may receive a light (hereinafter, referred to as the first reflective light RR1) which is made as the first emitted light is reflected from the wall surface of the chamber 100. In addition, the light receiver 210 may receive a light (hereinafter, referred to as the second reflective light RR2) which is made as the second emitted light is reflected from the wall surface of the chamber 100. The light receiver 210 may have a height higher than the first height He1 of the first light emitter 221. Accordingly, the light receiver 210 may receive the first and second reflective lights RR1 and RR2.

The first and second reflective lights RR1 and RR2 reflected from the wall surface of the chamber 100 may be additionally reflected from the ceiling part or the diffuser 130 of the chamber 100. For example, the first and second reflective lights RR1 and RR2 reflected from the wall surface of the chamber 100 may be additionally reflected from the bottom surface of the diffuser 130. The first and second reflective lights RR1 and RR2 reflected from the ceiling part of the chamber 100 or the diffuser 130 may be reflected from one or more wall surfaces of the chamber 100. The first and second reflective lights RR1 and RR2 additionally reflected may be provided to the measurement sensor 20. At least any one of the plurality of sensing ports 200 provided in the measurement sensor 20 may receive the first and second reflective lights RR1 and RR2 additionally reflected.

The length difference may be made between the length of the optical path of the first light and the length of the optical path of the second light. For example, the length difference, which corresponds to the height difference Hd12, may be made between the length of the optical path of the first light and the length of the optical path of the second light, due to the height difference Hd12 between the first light emitter 221 and the second light emitter 222. Accordingly, the difference in intensity as a function of a wavelength may be made between the first light and the third light.

Accordingly, in the measurement sensor 20 and the substrate processing apparatus 10 including the same, the radical density in the region between the first level LV1 and the second level LV2 may be measured.

In the measurement sensor and the substrate processing apparatus including the same according to embodiments of the present disclosure, the light emitter to irradiate light into the processing space and the light receiver to receive the light reflected in the chamber may be provided to measure the radical density in the processing space.

In addition, in the measurement sensor and the substrate processing apparatus including the same according to embodiments of the present disclosure, the radical density may be measured at the specific level from the stage for performing the manufacturing process.

In addition, in the measurement sensor and the substrate processing apparatus including the same according to embodiments of the present disclosure, the radical density may be measured in the region having a specific height, due to the first light emitter and the second light emitter having heights different from each other.

In addition, in the measurement sensor and the substrate processing apparatus including the same according to embodiments of the present disclosure, the radical density may be measured in the regions having various heights, due to the first light emitter, the second light emitter, and the third light emitter having heights different from each other.

In addition, in the measurement sensor and the substrate processing apparatus including the same according to embodiments of the present disclosure, the radical density may be more exactly measured, due to the plurality of light emitting groups, each of which includes the first light emitter and the second light emitter.

In addition, in the measurement sensor and the substrate processing apparatus including the same according to embodiments of the present disclosure, the radical density may be measured in the regions having various heights, due to the light emitter variable in height.

In addition, as the measurement sensor according to embodiments of the present disclosure may include a memory device to store data that may be received through the sensing port, the measurement sensor may be a wireless type device. For example, the measurement sensor may store data, which is collected on the stage, in the memory device, and the measurement sensor may be connected to the controlling system to determine the stored data. Accordingly, the measurement sensor may be a wireless type device, without a physical data connection to the outside, e.g., a data connection through a cable.

In addition, the measurement sensor according to embodiments of the present disclosure may include a wireless communication device to transmit the data which may be received through the sensing port through wireless communication. Accordingly, the measurement sensor may transmit the collected data to the controlling system. For example, the measurement sensor may transmit the collected data to the controlling system in real time. Accordingly, the measurement sensor may be a wireless type device, without a physical connection to the outside.

In addition, the measurement sensor according to embodiments of the present disclosure may include a power supplier configured to supply power to the sensing port. Accordingly, the measurement sensor may operate without power supplied from the outside. Accordingly, the measurement sensor may be provided as a wireless type device, without a physical connection to the outside, e.g., a data connection through a cable.

In addition, in the measurement sensor and the substrate processing apparatus including the same according to embodiments of the present disclosure, a shape of the plate may be substantially identical to a shape of the substrate disposed on the stage. Accordingly, the measurement sensor may be loaded onto the stage. In addition, the measurement sensor may measure the radical density at the surface level of a substrate that may be loaded onto the stage in a manufacturing process.

In addition, in the measurement sensor and the substrate processing apparatus including the same according to embodiments of the present disclosure, the radical density may be measured at a specific position in the horizontal direction, due to the plurality of sensing ports arranged radially from the center portion of the plate. For example, the measurement sensor may measure whether the radical density is uniformly formed in the horizontal direction.

In addition, in the measurement sensor and the substrate processing apparatus including the same according to embodiments of the present disclosure, the radical density may be measured at a specific position between the measurement sensor and the diffuser, due to the measurement sensor based on light irradiated to the diffuser disposed on the stage.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A measurement sensor for measuring density of a material in a chamber comprising:
a plate configured to be positioned on a stage of the chamber; and
a plurality of sensing ports provided on the plate,
wherein each of the plurality of sensing ports comprises:
at least one light emitter configured to emit light within the chamber; and
a light receiver configured to receive the light reflected within the chamber.

2. The measurement sensor of claim 1, wherein the at least one light emitter includes:
a first light emitter having a first height and configured to emit a first incident light of the light; and
a second light emitter having a second height different than the first height, and configured to emit a second incident light of the light.

3. The measurement sensor of claim 2, wherein the at least one light emitter further comprises:
a third light emitter having a third height different than the first height and the second height, and configured to emit a third incident light of the light.

4. The measurement sensor of claim 2,
wherein the measurement sensor comprises a plurality of light emitting groups, each light emitting group including a plurality of light emitters, and
wherein a first light emitting group of the plurality of light emitting groups includes the first light emitter and the second light emitter.

5. The measurement sensor of claim 1, wherein the at least one light emitter comprises:
a light emitter configured to be adjustable in height.

6. The measurement sensor of claim 1, further comprising:
a sensor controller configured to select at least one of sensing port the plurality of sensing ports, and control a light emitting operation of the at least one sensing port that is selected.

7. The measurement sensor of claim 6, wherein the sensor controller is connected to a controlling system through a cable, and configured to transmit data corresponding to light received by the plurality of sensing ports to the controlling system.

8. The measurement sensor of claim 1, further comprising:
a memory device configured to store data corresponding to light which is received by the plurality of sensing ports.

9. The measurement sensor of claim 1, further comprising:
a wireless communication device configured to transmit data corresponding to light received by the plurality of sensing ports, and which is received from the plurality of sensing ports, to a controlling system.

10. The measurement sensor of claim 1, wherein a planar shape of the plate is substantially the same as a planar shape of a substrate configured to be disposed on a stage disposed in the chamber.

11. The measurement sensor of claim 1, wherein the plurality of sensing ports are arranged radially from a center portion of the plate, and spaced apart from each other.

12. A substrate processing apparatus comprising:
a chamber defining a processing space therein;
a plasma generator configured to generate plasma;
a stage disposed in the processing space;
a diffuser disposed at a ceiling part of the chamber, and configured to supply the plasma into the processing space; and
a measurement sensor configured to be disposed on the stage to face the diffuser,
wherein the measurement sensor comprises:
a plate configured to be positioned on the stage; and
a plurality of sensing ports provided on the plate, and
wherein each of the plurality of sensing ports comprises:
at least one light emitter configured to irradiate light toward the diffuser; and
a light receiver configured to receive the light reflected from the diffuser.

13. The substrate processing apparatus of claim 12, wherein the diffuser comprises:
an ion blocker configured to filter out ions generated from the plasma generator.

14. The substrate processing apparatus of claim 12, wherein the diffuser comprises:
a shower head having a plurality of shower holes connecting the chamber to the plasma generator.

15. The substrate processing apparatus of claim 12, further comprising:
a controlling system electrically connected to the measurement sensor, and configured to receive data corresponding to light received by the plurality of sensing ports,
wherein the controlling system is configured to calculate a density of radicals in the chamber, based on the received data.

16. The substrate processing apparatus of claim 15, wherein the at least one light emitter comprises:
a first light emitter having a first light emitting surface positioned at a first level from a top surface of the plate, and configured to emit a first incident light through the first light emitting surface; and
a second light emitter having a second light emitting surface positioned at a second level from the top surface of the plate, and configured to emit a second incident light through the second light emitting surface,
wherein the first level is different from the second level, and
wherein the controlling system is configured to calculate the density of the radicals in a region between the first level and the second level, based on the received data.

17. A substrate processing apparatus comprising:
a chamber defining a processing space therein;
a plasma generator configured to supply plasma into the processing space;
a stage disposed in the processing space; and
a measurement sensor configured to be positioned on the stage,
wherein the measurement sensor comprises:
a plate; and
a plurality of sensing ports provided on the plate, and
wherein each of the plurality of sensing ports comprises:
at least one light emitter configured to irradiate light toward an inner surface of the chamber; and
a light receiver configured to receive the light reflected from the inner surface of the chamber.

18. The substrate processing apparatus of claim 17, further comprising:
a diffuser disposed at a ceiling part of the chamber, and configured to supply the plasma into the processing space; and
wherein the light receiver is configured to receive the light reflected from the inner surface of the chamber.

19. The substrate processing apparatus of claim 18, wherein the at least one light emitter comprises:
a first light emitter having a first light emitting surface inclined with respect to a top surface of the plate, and configured to irradiate a first incident light to the inner surface of the chamber through the first light emitting surface; and
a second light emitter having a second light emitting surface inclined with respect to the top surface of the plate, and configured to irradiate a second incident light to the inner surface of the chamber through the second light emitting surface,
wherein a first lower end portion of the first light emitting surface is positioned at a first level from the top surface of the plate,
wherein a second lower end portion of the second light emitting surface is positioned at a second level from the top surface of the plate, and
wherein the first level is different from the second level.

20. The substrate processing apparatus of claim 19, further comprising:
a controlling system configured to receive data from the plurality of sensing ports corresponding to light received by the plurality of sensing ports,
wherein the controlling system is configured to calculate a density of radicals in a region between the first level and the second level, based on the data.
